(19) United States
(12) Patent Application Publication
(10) Pub. No.: US 2003/0062574 A1
(43) Pub. Date: Apr. 3, 2003

(54) Double vertical channel thin film transistor for SRAM and process of making the same

(76) Inventor: In-Cha Hsieh, Hsinchu Hsien (TW)

Correspondence Address: Merchant & Gould P.C., P.O. Box 2903, Minneapolis, MN, 55402-0903, US

(21) Appl. No.: 10/141,892

(22) Filed: May 8, 2002

(30) Foreign Application Priority Data
Oct. 3, 2001 (TW) 90124401

(51) Int. Cl. H01L 21/8238; H01L 31/113; H01L 29/94

(52) U.S. Cl. 257/379; 438/210; 438/238

(57) ABSTRACT

A double vertical channel thin film transistor (DVC TFT) for static random access memory (SRAM) and method of making the same is disclosed. The DVC TFT of the present invention has a double vertical channel structure, this channel structure side steps the photolithography limitation because the deep-submicrometer channel length is determined by the thickness of gate, thereby decreasing the channel length substantially.

### BACKGROUND OF THE INVENTION

1. Field of the Invention

The present invention relates in general to a double vertical channel thin film transistor (DVC TFT) and method of making the same. In particular, the present invention relates to a double vertical channel thin film transistor (DVC TFT) for static random access memory (SRAM) and method of making the same.

2. Description of the Related Art

Conventionally, thin film transistors (TFTs) are used for high-density SRAM technology as pull-up devices in six-transistor complementary metal-oxide semiconductor (CMOS) cells. Conventional SRAM cells using polysilicon (poly-Si) resistors as the load element can't meet demands such as small cell size, low standby current, better data retention stability and soft error immunity. Therefore, a stacked PMOS poly-Si transistor is implemented in high density SRAM such as 1M bit and beyond.

Since the standby current of a chip increases as the bit capacity increases, small OFF currents become more and more important. In the conventional TFT fabrication process, dual gate, LDD structure and hydrogenation are the most widely used methods for reducing OFF currents. However, all these processes to lower poly-Si TFT OFF currents are complicated and expensive. On the other hand, the conventional processes of the stacked PMOS poly-Si TFT using a bottom gate device structure need an additional mask to define the channel length, increasing the cost of the processes. Furthermore, even when poly-Si TFTs are used as load devices, it is difficult to reduce the memory cell area below 10 μm² because of the physical limitation inherent in trying to use the conventional i-line (365 nm) stepper to delineate from 0.4 to 0.3 μm pattern. Consequently, improvement of the fabrication process along with decreasing the channel length is very important.

### SUMMARY OF THE INVENTION

The present invention is intended to overcome the above-described disadvantages.

Therefore, an object of the present invention is to provide a double vertical channel thin film transistor (DVC TFT) for SRAM, including a gate layer formed on a substrate; a first insulator layer formed on the substrate and the gate layer; a semiconductor layer having a first end and a second end formed on the first insulator layer exposing the edges of the first insulator layer, a source/drain area being formed on each of the first and second ends of the semiconductor layer, two channel areas being formed on the surface of the first insulator layer substantially perpendicular to each of the source/drain areas, respectively, and a doped area being formed between the two channel areas; a second insulator layer formed on the channel areas and the doped area, exposing the source/drain areas; and a metal layer formed on the surface of the source/drain areas and the exposed first insulator layer.

Another object of the present invention is to provide a process for forming a double vertical channel thin film transistor (DVC TFT) for SRM, including the steps of forming a gate layer on a substrate; forming a first insulator layer on the substrate and the gate layer; forming a semiconductor layer on the first insulator layer; implanting ions to the semiconductor layer; removing the edges of the semiconductor layer to expose the first insulator layer and define a source/drain area, two channel areas, and a doped area; forming a second insulator layer covering over the channel areas and the doped area; and forming a metal layer on the source/drain area and the exposed first insulator layer.

As mentioned above, the DVC TFT with a dual gate and offset structure reduces leakage current, and the process defines a channel without an additional mask. Hence, the present invention successfully decreases the fabrication cost and simplifies the process. Moreover, the double vertical channel structure of the DVC TFT side steps the photolithography limitation because the deep-submicrometer channel length is determined by the thickness of gate, thereby decreasing the channel length substantially.

### BRIEF DESCRIPTION OF THE DRAWINGS

The present invention can be more fully understood by reading the subsequent detailed description in conjunction with the examples and references made to the accompanying drawings, wherein:

FIGS. 1 to 6 are sectional views showing an embodiment of the process for fabricating the DVC TFT according to the present invention.

### DETAILED DESCRIPTION OF THE PREFERRED EMBODIMENT

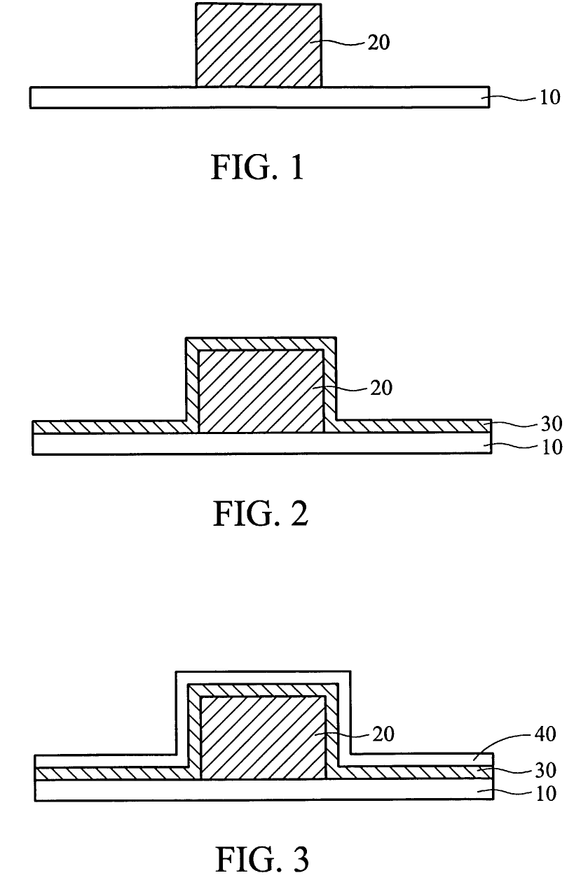

As shown in FIG. 1, a gate layer 20 is deposited on a substrate 10. The gate layer 20, is preferably deposited by APCVD, LPCVD, PECVD, sputtering system, or e-gun evaporation, and is preferably composed of doped polysilicon, metal, alloy, or metal silicide.

As shown in FIG. 2, a gate insulator layer 30 is deposited on the substrate 10 and the gate layer 20. The gate insulator layer 30, is preferably deposited by APCVD, LPCVD, PECVD, sputtering system, or e-gun evaporation, and is preferably composed of nitride, oxide, or oxynitride.

As shown in FIG. 3, a semiconductor layer 40 is deposited on the gate insulator layer 30. The semiconductor layer 40, is preferably deposited by APCVD, LPCVD, PECVD, sputtering system, or e-gun evaporation, and is preferably composed of single crystal silicon, polysilicon, amorphous silicon, or silicon-germaium.

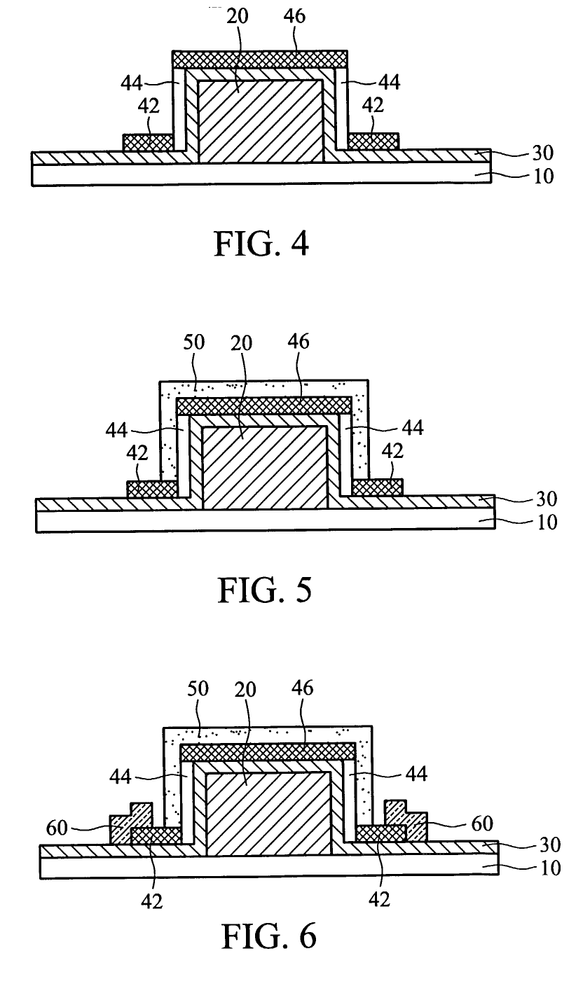

Furthermore, as shown in FIG. 4, ions are implanted to the semiconductor layer 40 and the edges of the semiconductor layer 40 are etched to expose the gate insulator layer 30 and define a source/drain area 42, two channel areas 44, and a doped area 46. The above-mentioned two channel areas 44 are called double vertical channel (DVC), and the DVC structure side steps the conventional photolithography limitation because the deep-submicrometer channel length is determined by the thickness of the gate, thereby decreasing the channel length substantially. Moreover, because the channel is formed without an additional mask to define, the fabrication cost is decreased and the process is simplified.

As shown in FIG. 5, an insulator layer 50 is deposited on the channel areas 44 and the doped area 46. The insulator layer 50, is preferably deposited by APCVD, LPCVD, PECVD, sputtering system, or e-gun evaporation, and is preferably composed of nitride, oxide, or oxynitride.

As shown in FIG. 6, a metal layer 60 is deposited on the source/drain area 42 and the exposed gate insulator layer 30. The above-mentioned metal layer 60, is preferably deposited by LPCVD, sputtering system, or e-gun evaporation, and is preferably composed of metal, alloy, or metal silicide.

Therefore, according to the above-mentioned process, a double vertical channel thin film transistor (DVC TFT) for SRAM is obtained. Refer to FIG. 6. The DVC TFT for SRAM includes a gate layer 20 formed on a substrate 10; a gate insulator layer 30 formed on the substrate 10 and the gate layer 20; a semiconductor layer 40 formed on the gate insulator layer 30 exposing the edges of the gate insulator layer 30, wherein a source/drain area 42 is formed on the ends of the semiconductor layer 40, and two channel areas 44 are formed on the surface of the gate insulator layer 30 substantially perpendicular to the source/drain area 42, and a doped area 46 is formed between the two channel areas 44; a insulator layer 50 formed on the channel areas 44 and the doped area 46, exposing the source/drain area 42; and a metal layer 60 formed on the surface of the source/drain area 42 and the exposed gate insulator layer 30.

Hence, the DVC TFT for SRAM of the present invention reduced leakage current because of dual gate and offset structure.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A double vertical channel thin film transistor for SRAM, comprising:
a gate layer formed on a substrate;
a first insulator layer formed on the substrate and the gate layer;
a semiconductor layer having a first end and a second end formed on the first insulator layer exposing the edges of the first insulator layer, a source/drain area being formed on each of the first and second ends of the semiconductor layer, two channel areas being formed on the surface of the first insulator layer substantially perpendicular to each of the source/drain areas, respectively, and a doped area being formed between the two channel areas;
a second insulator layer formed on the channel areas and the doped area, exposing the source/drain areas; and
a metal layer formed on the surface of the source/drain areas and the exposed first insulator layer.

2. The double vertical channel thin film transistor for SRAM as claimed in claim 1, wherein the gate layer comprises doped polysilicon, metal, alloy, or metal silicide.

3. The double vertical channel thin film transistor for SRAM as claimed in claim 1, wherein the first insulator layer comprises nitride, oxide, or oxynitride.

4. The double vertical channel thin film transistor for SRAM as claimed in claim 1, wherein the semiconductor layer comprises single crystal silicon, polysilicon, amorphous silicon, or silicon-germaium.

5. The double vertical channel thin film transistor for SRAM as claimed in claim 1, wherein the second insulator layer comprises nitride, oxide, or oxynitride.

6. The double vertical channel thin film transistor for SRAM as claimed in claim 1, wherein the metal layer comprises metal, alloy, or metal silicide.

7. A process for formation of double vertical channel thin film transistor for SRAM, comprising the steps of:
forming a gate layer on a substrate;
forming a first insulator layer on the substrate and the gate layer;
forming a semiconductor layer on the first insulator layer;
implanting ions to the semiconductor layer;
removing the edges of the semiconductor layer to expose the first insulator layer and define a source/drain area, two channel areas, and a doped area;
forming a second insulator layer covering over the channel areas and the doped area; and
forming a metal layer on the source/drain area and the exposed first insulator layer.

8. The process for formation of double vertical channel thin film transistor for SRAM as claimed in claim 7, wherein the gate layer comprises doped polysilicon, metal, alloy, or metal silicide.

9. The process for formation of double vertical channel thin film transistor for SRAM as claimed in claim 7, wherein the first insulator layer comprises nitride, oxide, or oxynitride.

10. The process for formation of double vertical channel thin film transistor for SRAM as claimed in claim 7, wherein the semiconductor layer comprises single crystal silicon, polysilicon, amorphous silicon, or silicon-germaium.

11. The process for formation of double vertical channel thin film transistor for SRAM as claimed in claim 7, wherein the second insulator layer comprises nitride, oxide, or oxynitride.

12. The process for formation of double vertical channel thin film transistor for SRAM as claimed in claim 7, wherein the metal layer comprises metal, alloy, or metal silicide.
